(19) United States
(12) Patent Application Publication
(10) Pub. No.: US 2022/0406523 A1
(43) Pub. Date: Dec. 22, 2022

(54) CAPACITORS IN A GLASS SUBSTRATE

(71) Applicant: Intel Corporation, Santa Clara, CA (US)

(72) Inventors: Telesphor KAMGAING, Chandler, AZ (US); Veronica STRONG, Hillsboro, OR (US); Neelam PRABHU GAUNKAR, Chandler, AZ (US); Aleksandar ALEKSOV, Chandler, AZ (US); Georgios C. DOGIAMIS, Chandler, AZ (US); Hiroki TANAKA, Gilbert, AZ (US)

(21) Appl. No.: 17/350,164

(22) Filed: Jun. 17, 2021

(51) Int. Cl. H01G 4/002

(52) U.S. Cl. CPC H01G 4/002

(57) ABSTRACT

Embodiments described herein may be related to apparatuses, processes, and techniques related to creating capacitors at the interface of a glass substrate. These capacitors may be three-dimensional (3-D) capacitors formed using trenches within the glass core of the substrate using laser-assisted etching techniques. A first electrode may be formed on the glass, including on the surface of trenches or other features etched in the glass, followed by a deposition of a dielectric material or a capacitive material. A second electrode may then be formed on top of the dielectric material. Other embodiments may be described and/or claimed.

### FIELD

Embodiments of the present disclosure generally relate to the field of semiconductor packaging, and in particular to constructing capacitors within a package.

### BACKGROUND

Continued growth in virtual machines and cloud computing will continue to increase the demand for increased power and reduced components within packages and substrates.

### BRIEF DESCRIPTION OF THE DRAWINGS

FIG. 1 illustrates multiple examples of laser-assisted etching of glass interconnects processes, in accordance with embodiments.

FIG. 2 illustrates a high-density deep trench capacitor in a glass core, in accordance with various embodiments.

FIG. 3 illustrates a high-density deep trench capacitor in a glass core with a filled top electrode, in accordance with various embodiments.

FIG. 4 illustrates an array of micro-pillars to create a high-density capacitor, in accordance with various embodiments.

FIG. 5 illustrates an alternative high-density deep trench capacitor in a glass core, in accordance with various embodiments.

FIGS. 6A-6D illustrate various side views of a package that include one or more high-density deep trench capacitors, in accordance with various embodiments.

FIGS. 7A-7B illustrate examples of multilayered deep trench capacitors, in accordance with various embodiments.

FIG. 8 illustrates an example process for creating a high density deep trench capacitor, in accordance with various embodiments.

FIG. 9 schematically illustrates a computing device, in accordance with embodiments.

### DETAILED DESCRIPTION

Embodiments described herein may be related to apparatuses, processes, and techniques for creating capacitors that are formed at the interface of a glass substrate. In embodiments, these capacitors may be three-dimensional (3-D) capacitors that are formed using trenches within the glass core of the substrate using laser-assisted etching techniques. A first electrode may be formed on the glass, including on the surface of trenches or other features etched in the glass, followed by a deposition of a dielectric material or a capacitive material. A second electrode may then be formed on top of the dielectric material. In embodiments, package build up layers may then be formed on either side of the glass core of the glass substrate to electrically couple with the capacitor in the glass. Embodiments described herein may result in a capacitor with high capacitance density due to deep trenches made into the glass, where the trenches may be several hundred microns deep. In addition, embodiments may result in high level voltage breakdown, for example of up to 12 volts for certain capacitor dielectric properties and thickness.

Power delivery solutions for computing within packages are facilitated by high-density capacitors that are integrated within the packages. In legacy implementations these capacitors have been integrated into packages using planar structures. This legacy approach requires a large area, material with high dielectric constant, and/or an extremely thin film, for example 10 nm or less. These legacy approaches frequently have reliability challenges of legacy capacitors, including low breakdown voltages of less than or equal to 1 volt.

Embodiments described herein include high density capacitors formed on the surface of a glass substrate or a glass core of a substrate core, using glass etching techniques described herein. These techniques may provide deep trenches within the glass core to enhance capacitance density. Embodiments may also include low series resistant inductors, using the glass etching techniques described herein, for use in power delivery, where the resistance of the inductance may be decreased by extending the trace thickness inside the glass core, which may be achieved by deep trenches within the glass core.

One or more laser sources followed by wet-etching may be used to create through hole vias or trenches into the glass panel or glass wafer. Using these laser techniques, vias may be created with a small diameter, for example on the order of less than 10 μm, and may be spaced with a pitch on the order of 50 μm or less. Other vias may be created with different diameter sizes. These vias may be later plated for filled to create electrical pathways through the bridge. These techniques may be used to create vias in the glass wafer or panel that have high aspects ratios, for example 40:1 or 50:1.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

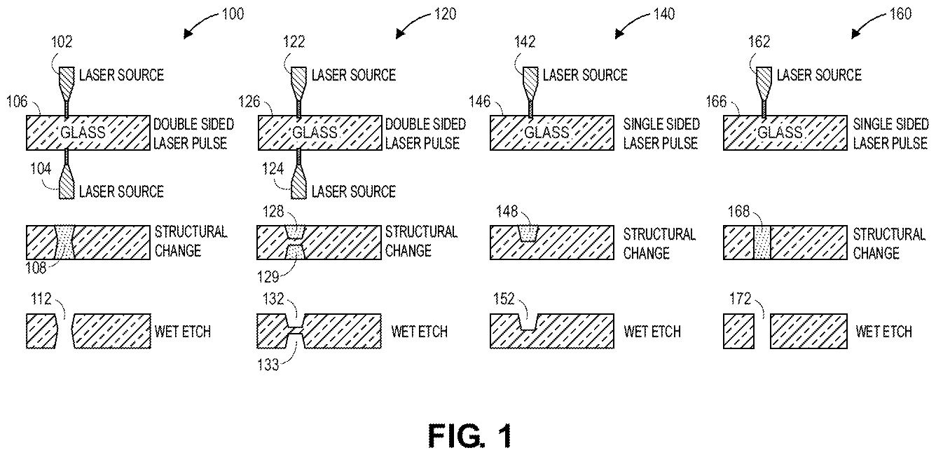

FIG. 1 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 100 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 112 is created by laser pulses from two laser sources 102, 104 on opposite sides of a glass wafer 106. As used herein, a through drill and a through via refers to when the drill or the via starts on one side of the glass/substrate and ends on the other side. A blind drill and a blind via refers to when the drill or the via starts on the surface of the substrate and stops partially inside the substrate. In embodiments, the laser pulses from the two laser sources 102, 104 are applied perpendicularly to the glass wafer 106 to induce a morphological change 108, which may also be referred to as a structural change, in the glass that encounters the laser pulses. This morphological change 108 includes changes in the molecular structure of the glass to make it easier to etch out (remove a portion of the glass). In embodiments, a wet etch process may be used.

Diagram 120 shows a high level process flow for a double blind shape. A double blind shape 132, 133 may be created by laser pulses from two laser sources 122, 124, which may be similar to laser sources 102, 104, that are on opposite sides of the glass wafer 126, which may be similar to glass wafer 106. In this example, adjustments may be made in the laser pulse energy and/or the laser pulse exposure time from the two laser sources 122, 124. As a result, morphological changes 128, 129 in the glass 126 may result, with these changes making it easier to etch out portions of the glass. In embodiments, a wet etch process may be used.

Diagram 140 shows a high level process flow for a single-blind shape, which may also be referred to as a trench. In this example, a single laser source 142 delivers a laser pulse to the glass wafer 146 to create a morphological change 148 in the glass 146. As described above, these morphological changes make it easier to etch out a portion of the glass 152. In embodiments, a wet etch process may be used.

Diagram 160 shows a high level process flow for a through via shape. In this example, a single laser source 162 applies a laser pulse to the glass 166 to create a morphological change 168 in the glass 166, with the change making it easier to etch out a portion of the glass 172. As shown here, the laser pulse energy and/or laser pulse exposure time from the laser source 162 has been adjusted to create an etched out portion 172 that extends entirely through the glass 166.

With respect to FIG. 1, although embodiments show laser sources 102, 104, 122, 124, 142, 162 as perpendicular to a surface of the glass 106, 126, 146, 166, in embodiments, the laser sources may be positioned at an angle to the surface of the glass, with pulse energy and/or pulse exposure time variations in order to cause a diagonal via or a trench, or to shape the via, such as 112, 172, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 1, through hole vias 112, 172 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

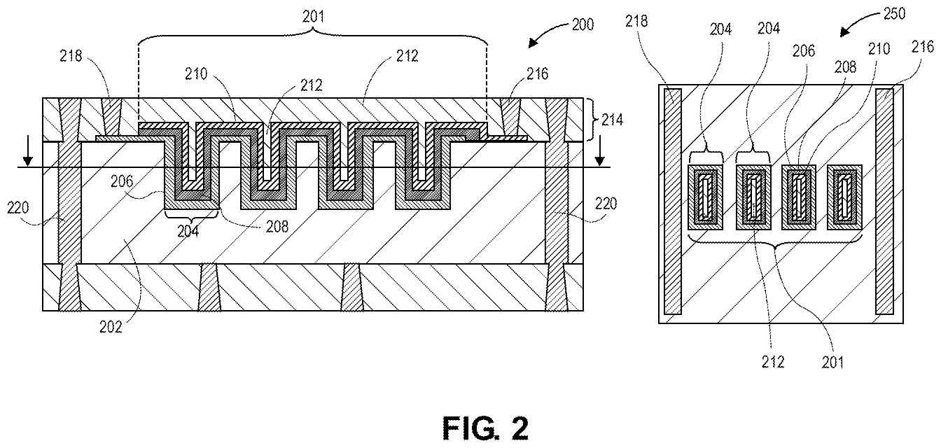

FIG. 2 illustrates a high-density deep trench capacitor in a glass core, in accordance with various embodiments. FIG. 2 includes a side view of the glass core substrate 200, as well as a top-down cross-section 250. Substrate 200 includes a glass core 202 that includes one or more trenches 204 created into a surface of the glass core 202. In embodiments, the trenches 204 may be created using LEGIT etching process described above with respect to FIG. 1. The glass core 202 may be similar to the glass 106, 126, 146, 166 prior to application of the etching process to create the one or more trenches 204.

The trench 204 includes a bottom electrode 206 in contact with the trench 204 walls or bottom, a capacitor material 208 in contact with the bottom electrode 206, and the top electrode 210 in contact with the capacitor material 208. In embodiments, the bottom electrode 206 in the top electrode 210 may include, for example but not limited to, Cu, Ni, Fe, Ru, Au, Ir, Pt, IrO₂, RuO₂, Ag, and/or AgO. In embodiments, the capacitor material may include, for example but not limited to, SiO₂, Si3N4, HfO₂, HfZrO₂, TiO₂, ZrO₂, SrTiO₂, BaTiO₂, BaSrTiO₂. In embodiments, the bottom electrode 206 and the top electrode 210 are not in direct physical or electrical contact. In embodiments, the trenches 204 may have a depth on the order of a few microns to several hundred microns. In embodiments, there may be a dielectric 212, which may be a buildup dielectric, that is included in one or more of the trenches 204. In embodiments, the top of the electrode 210 may be above a surface of the glass core 202, and as a result take up one or more of the layers of the first build up layer 214. In embodiments, the surface of the glass core 202 may be etched (not shown) either prior to or after trench 204 formation, so that the top layer of the top electrode 210 is even with or below the surface (not shown) of the glass core 202.

The first build up layer 214 may include a via 216 to electrically couple with the top electrode 210, and may include a second via 218 to electrically couple with the bottom electrode 206. In other embodiments, electrodes (not shown) may be used to couple the bottom electrode 206 or the top electrode 210 to various redistribution layers (RDL) within the first build up layer 214. In embodiments, planes 220 may be created within the glass core 202 in order to provide isolation for the capacitor 201. In embodiments, the top electrode 210 may be conformally plated. In embodiments, the thickness of the dielectric material 210 may vary from a few nanometers to a few microns, based upon the capacitance density and the targeted breakdown voltage.

Top-down cross-section 250 shows trenches 204, bottom electrode 206, capacitor material 208, top electrode 210, and dielectric material 212. In addition, the conductive vias 216, 218 are also shown. It should be noted that although the trenches 204 are shown as square trenches, they may take any other shape, including, for example, features with a curved shape or sloped walls, as discussed further below. The depth, width, shape, and/or spacing of the trenches 204, as well as the thickness of the applied bottom electrode 206, capacitive material 208, and/or top electrode 210 may be chosen to achieve a particular desired characteristic of the resulting capacitor 201.

An appropriate contact metal may be chosen to minimize capacitor leakage current in the desired operational voltage range, for example less than or equal to 12 V, and thus also minimize capacitor losses. As a non-limiting example, there may be a hard limit of 100 mA/mm² of the leakage current that flows through the capacitor during operation, which means that this current cannot be reached for up to the maximum voltage the capacitor is going to experience during operation.

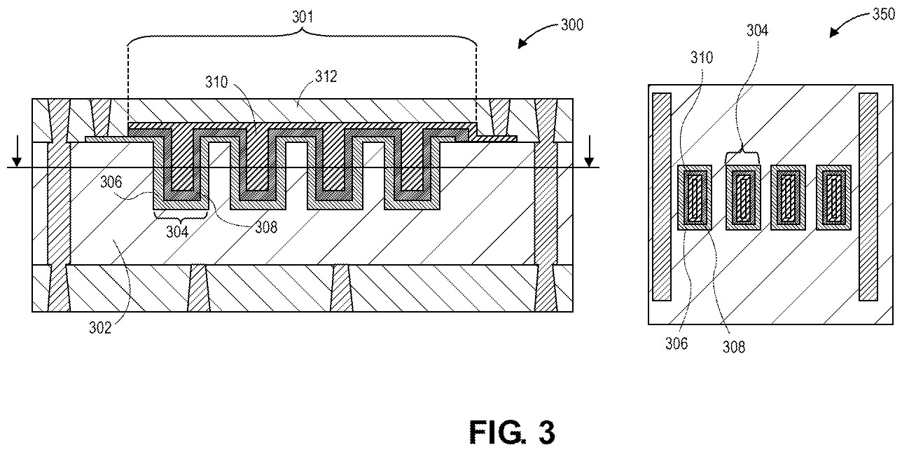

FIG. 3 illustrates a high-density deep trench capacitor in a glass core with a filled top electrode, in accordance with various embodiments. FIG. 3 includes a side view of the glass core substrate 300, as well as a top-down cross-section 350, which may be similar to glass core substrate 200 and top-down cross-section 250 of FIG. 2. In core substrate 300, the top electrode 310, which may be similar to top electrode 210 of FIG. 2, completely fills the trench 304, which may be similar to trench 204 of FIG. 2. As a result, none of the dielectric 312, which may be similar to dielectric 212 FIG. 2, is disposed within the trench 304.

Top-down cross-section 350 shows the trench 304 that includes the bottom electrode 306 and the capacitive material 308, which may be similar, respectively to electrode 206 and capacitive material 208 of FIG. 2, as well as top electrode 310. In this embodiment, no dielectric 312 is within the trenches 304. However, in other embodiments, multiple trenches 304 may have different characteristics, including different shapes and/or sizes as discussed above, but may also include none or varying amounts (not shown) of dielectric 312 within the trenches 304. This may be used to achieve a particular desired characteristic of the resulting capacitor 301.

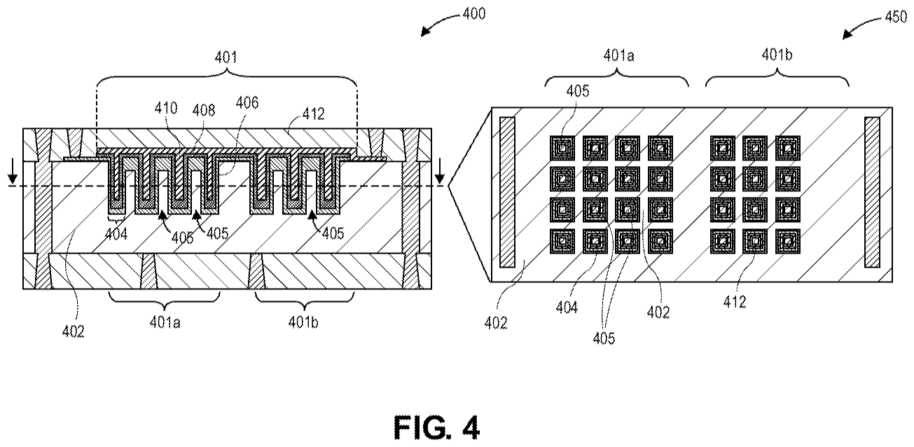

FIG. 4 illustrates an array of micro-pillars to create a high-density capacitor, in accordance with various embodiments. FIG. 4 includes a side view of the glass core substrate 400, as well as a top-down cross-section 450, which may be similar to glass core substrate 300 and top-down cross-section 350 of FIG. 3. Glass core substrate 400 includes a capacitor 401, that includes a plurality of pillars 405 over which a bottom electrode 406, a capacitive material 408, and a top electrode 410, which may be similar to bottom electrode 306, capacitive material 308, and top electrode 310 of FIG. 3, may be placed. Pillars 405 may include portions of the glass core 402 that have not been etched away during the LEGIT etching process. The walls and floors of the trench-like areas 404 that surround the pillars 405 also receive a deposition of the bottom electrode 406, capacitive material 408, and top electrode 410, which may be placed over the top of the pillars 405 as well. A portion of a buildup layer 412, which may be similar to buildup layer 312 of FIG. 3, may couple with the top electrode 310.

As shown in glass substrate 450 with a top-down cross section view, the pillars may be arranged as an array, and may be arranged in different sections, such as section 401a and 401b. In embodiments, the array may be something other than a rectangular array, and may include any other pattern of pillars. In other embodiments, the pillars 405 themselves may be elongated (not shown) to form fin-like structures over which the bottom electrode 406, capacitive material 408, and top electrode 410 layers may be placed. In embodiments, the pillars 405 may have sides that slope inward or outward, may be vertical with no slope, or maybe rounded.

In other similar, related embodiments, wells (not shown), instead of pillars 405, etched into the glass substrate 402, with the bottom electrode 406, capacitive material 408, and top electrode 410 layers flowing over and into the wells (not shown). In embodiments, there may be a combination of wells (not shown), pillars 405, and/or any other structures etched into the glass substrate in order to provide a high surface area contact to increase capacitance density or capacitance per unit area of capacitor 401.

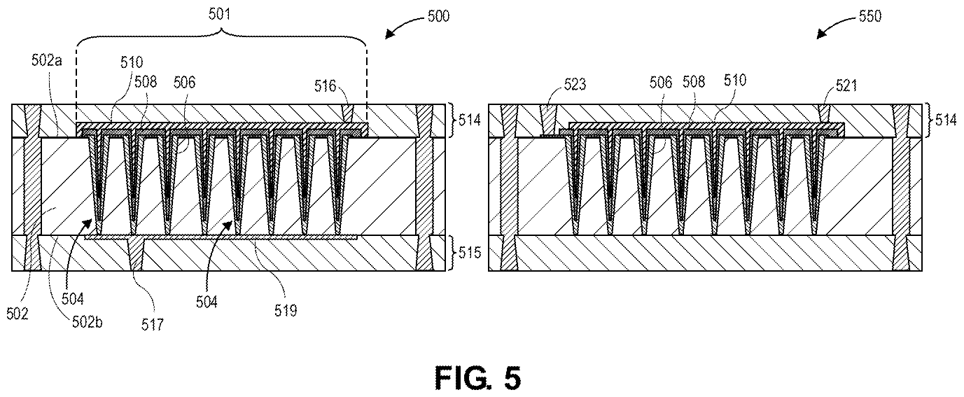

FIG. 5 illustrates an alternative high-density deep trench capacitor in a glass core, in accordance with various embodiments. FIG. 5 includes a side view of a first glass core substrate 500, as well as a side view of a second glass core substrate 550, which may be similar to glass core substrate 300 of FIG. 3, or a glass core substrate 400 of FIG. 4.

As shown, structure 504, which may be similar to the trench structure 304 of FIG. 3, or the well structure 404 of FIG. 4, is etched into the glass core 502, which may be similar to glass core 302 of FIG. 3 or glass core 402 of FIG. 4. In embodiments, the structure 504 may extend from the top of the glass core 502a through the bottom of the glass core 502b. The structure 504 includes a bottom electrode 506, capacitive material 508, and top electrode 510 layers which may be similar to bottom electrode 406, capacitive material 408, and top electrode 410 of FIG. 4.

As shown, the sides or walls of the structures 504 may be tapered, and may form tapered trenches that may be similar to embodiments shown with respect to FIG. 3, or may be tapered wells that may be similar to embodiments shown with respect to FIG. 4. In embodiments, the structures 504 may be created using processes discussed above with respect to FIG. 1.

Regarding the first glass core substrate 500, within the capacitor 501, which may be similar to capacitor 401 of FIG. 4, the top electrode 510 may be physically proximate to the first buildup layer 514, which may be similar to first buildup layer 214 of FIG. 2. An electrical contact 516 may be made through the first buildup layer 514 to electrically couple with the top electrode 510. A bottom RDL layer 519 on the second buildup layer 515 may electrically couple with the bottom electrode 506 of the plurality of structures 504. In embodiments, the RDL layer 519 may be coupled with a via 517 to provide an electrical contact for the bottom electrode 506 outside of the substrate 500.

Regarding the second glass core substrate 550, the top electrode 510 may electrically couple with a via 521 within the first buildup layer 514, and the bottom electrode 506 may electrically couple with a via 523, also within the first buildup layer 514. In this way, both electrical contacts for the capacitor are accessible on one side of the package 550.

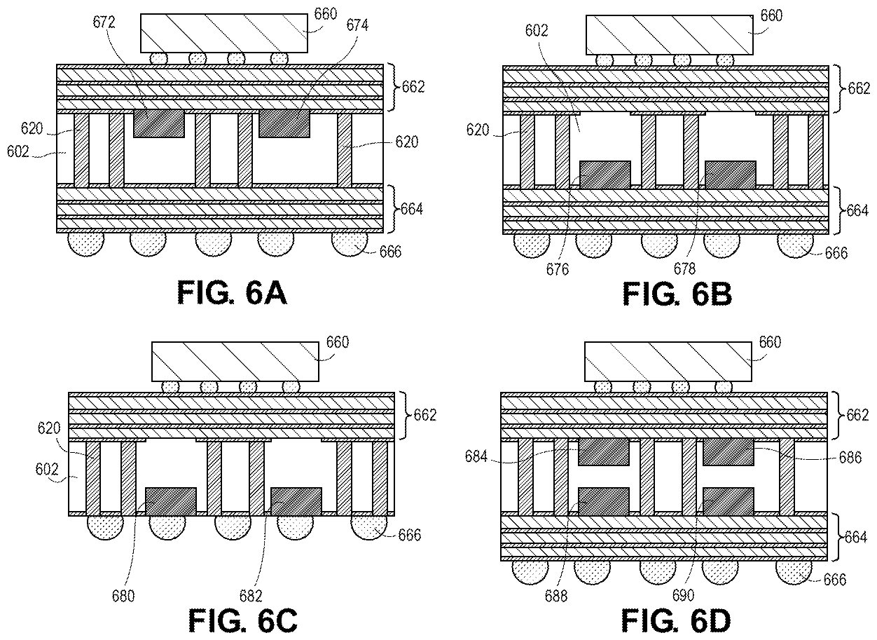

FIGS. 6A-6D illustrate various side views of a package that include one or more high-density deep trench capacitors, in accordance with various embodiments. FIG. 6A shows a package with an active die 660 coupled to a first buildup layer 662 of a package that is coupled with a glass core 602, and having a second buildup layer 664 opposite the first buildup layer 662. The second buildup layer 664 may electrically and/or physically couple with a substrate (not shown) using a ball grid array 666 as part of a second level interconnect (SLI). In the package embodiment of FIG. 6A, there are two capacitors 672, 674 that are embedded within a top side of the glass core 602, and electrically coupled with the first buildup layer 662 that is coupled with the active die 660. Filled metal planes 620 may be positioned within the glass core 602 to provide isolation during operation for the capacitors 672, 674. Note that in embodiments, the active die 660 may be an interposer or a passive die.

FIG. 6B shows a package that may be similar to FIG. 6A, but with the capacitors 676, 678 located at the bottom of the glass core 602 and coupled with the second buildup layer 664 that is opposite the active die 660.

FIG. 6C shows a package that may be similar to FIG. 6A, but with only the first buildup layer 662. Here, capacitors 680, 682 are embedded in the bottom of the glass core 602, and may electrically couple directly with the ball grid array 666 that forms the SLI.

FIG. 6D shows a package that may be similar to FIG. 6A, but with capacitors 684, 686 coupled with the first buildup layer 662, and capacitors 688, 690 coupled with the second buildup layer 664.

Note that with respect to FIG. 6A-6D, in some cases the active die 660 and the capacitors are on the same side of the glass core 602. In embodiments, although the buildup layers as shown are symmetric, it should be understood that an asymmetric stack up is likely, thus there may be as low as one buildup layer on the upper buildup layer 662. These embodiments would bring the capacitors closer in proximity to the active die 660, and therefore reduce parasitic inductance and resistance that may otherwise negatively affect the power delivery to the active die 660 through the capacitors. Note also that the capacitors may be used to deliver power to an active die 660, or to another package (not shown) that may be electrically coupled with the ball grid array 666.

FIG. 6A-6D show example of instantiations of a deep trench capacitor within a microelectronic package. It should be noted that the focus in these examples is on both integration density and the relative location of the capacitors versus active dies. For example, a deep trench capacitor on a glass package core may be used for power delivery to the active die, or a deep trench capacitor on a standalone glass piece may be used as a discrete capacitor in any system or module. In embodiments, any number of capacitors may be placed within a glass core or glass wafer.

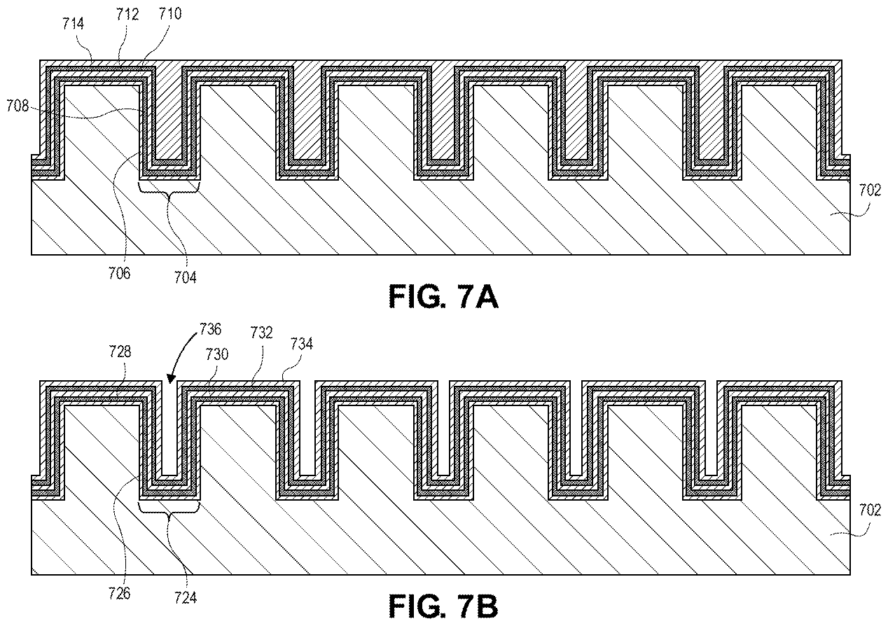

FIGS. 7A-7B illustrate examples of multilayered deep trench capacitors, in accordance with various embodiments. FIG. 7A shows a first example of a multilayered deep trench capacitor that includes a plurality of trenches 704, where the trenches include layers of conductive material 706, 710, 714 that are separated by layers of capacitive material 708, 712. As shown, the top layer of conductive material 714 may completely fill the plurality of trenches 704. In embodiments, additional layers of conductive material and capacitive material may be used to adjust the operational profile of the capacitor.

FIG. 7B shows a second example of a multilayered deep trench capacitor that includes a plurality of trenches 724, where the trenches include layers of conductive material 726, 730, 734, that are separated by layers of capacitive material 728, 732. As shown, the top layer of conductive material 734 does not completely fill the trenches 724. In embodiments, a space 736 may be left within the trenches 724. In embodiments, the thickness of the top layer of conductive material 734 may be adjusted to meet an operational profile of the capacitor.

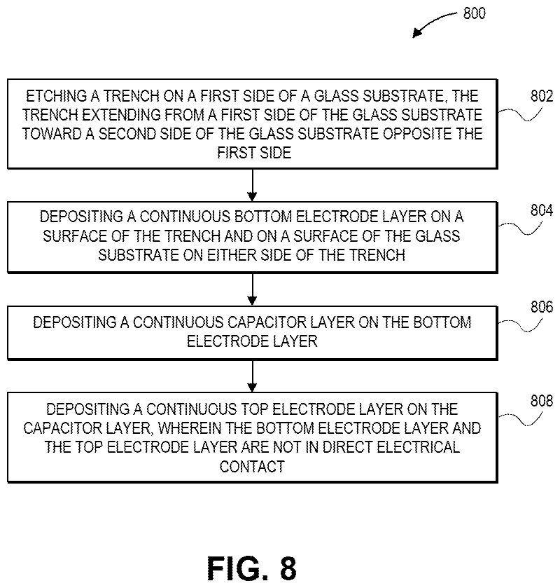

FIG. 8 illustrates an example process for creating a high density deep trench capacitor, in accordance with various embodiments. Process 800 may be implemented using the processes, techniques, apparatus, and/or systems described with respect to FIGS. 1-6D herein.

At block 802, the process may include etching a trench on a first side of a glass substrate, the trench extending from a first side of the glass substrate toward a second side of the glass substrate opposite the first side. The glass substrate may be similar to glass 126, 146 of FIG. 1, glass core 202 of FIG. 2, glass core 302 of FIG. 3, glass core 402 of FIG. 4, and glass core 502 of FIG. 5.

The trench may be similar to trench 132, 133, 148 of FIG. 1, trench 204 of FIG. 2, trench 304 of FIG. 3, trench like structure 404 of FIG. 4, or trench 504 of FIG. 5. In embodiments, the trench may be created using the LEGIT techniques described above with respect to FIG. 1.

At block 804, the process may further include depositing a continuous bottom electrode layer on a surface of the trench and on a surface of the glass substrate on either side of the trench. In embodiments, the continuous bottom electrode layer may be similar to bottom electrode 206 of FIG. 2, 306 of FIG. 3, 406 of FIG. 4, or 506 of FIG. 5.

At block 806, the process may further include depositing a continuous capacitor layer on the bottom electrode layer. In embodiments, the continuous capacitor layer may be similar to capacitor material 208 of FIG. 2, 308 of FIG. 3, 408 of FIG. 4, or 508 of FIG. 5.

At block 808, the process may further include depositing a continuous top electrode layer on the capacitor layer, wherein the bottom electrode layer and the top electrode layer are not in direct electrical contact. In embodiments, the continuous top electrode layer may be similar to top electrode 210 of FIG. 2, 310 of FIG. 3, 410 of FIG. 4, or 510 of FIG. 5.

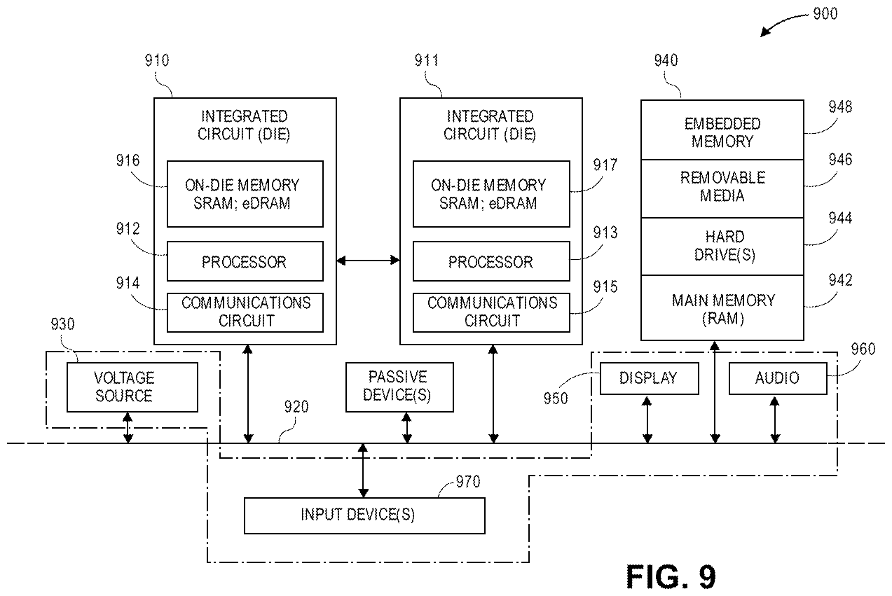

FIG. 9 schematically illustrates a computing device, in accordance with embodiments. The computer system 900 (also referred to as the electronic system 900) as depicted can embody all or part of capacitors in a glass substrate, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920. In embodiments, the voltage source 930 may include one or more of capacitors in a glass substrate.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, all or part of a high-speed bridge between a package and a component, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including all or part of capacitors in a glass substrate, according to any of the several disclosed embodiments and their equivalents, an electronic system, a computer system, one or more methods of fabricating an integrated circuit, and one or more methods of fabricating an electronic assembly that includes a package substrate implementing all or part of capacitors in a glass substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed processes used for capacitors in a glass substrate embodiments and their equivalents. A foundation substrate may be included, as represented by the dashed line of FIG. 9. Passive devices may also be included, as is also depicted in FIG. 9.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a capacitor comprising: a glass substrate having a first side and a second side opposite the first side; a trench in the first side of the substrate, the trench extending from the first side of the substrate toward the second side of the substrate; and a continuous layer of material coupled with a portion of the first side of the glass substrate at a first location, the layer extending from the first location onto a surface of the trench and to a second location of the first side of the glass substrate, the first location and the second location on opposite sides of the trench.

Example 2 includes the capacitor of example 1, wherein the trench is a plurality of trenches in substantially parallel planes.

Example 3 includes the capacitor of example 2, wherein a distance between each of the plurality of trenches is less than 2 nm.

Example 4 includes the capacitor of example 1, wherein a bottom of the trench is substantially parallel to the first side of the glass substrate.

Example 5 includes the capacitor of example 1, wherein a side of the trench is substantially perpendicular to the first side of the glass substrate.

Example 6 includes the capacitor 1, wherein a first side of the trench and a second side of the trench opposite the first side of the trench form a V shape.

Example 7 includes the capacitor of any one of examples 1-6, wherein the layer of material includes a plurality of capacitor layers interleaved with a plurality of electrode layers.

Example 8 includes the capacitor of example 7, wherein the trench includes a dielectric coupled with the top electrode layer.

Example 9 includes the capacitor of example 7, further comprising: a first electrical contact at the first location of the first side of the glass substrate electrically coupled with the bottom electrode layer; and a second electrical contact at the second location of the first side of the glass substrate electrically coupled with the top electrode layer.

Example 10 includes the capacitor of example 1, wherein the glass substrate is a glass core.

Example 11 is a method comprising: etching a trench on a first side of a glass substrate, the trench extending from a first side of the glass substrate toward a second side of the glass substrate opposite the first side; depositing a continuous bottom electrode layer on a surface of the trench and on a surface of the glass substrate on either side of the trench; depositing a continuous capacitor layer on the bottom electrode layer; and depositing a continuous top electrode layer on the capacitor layer, wherein the bottom electrode layer and the top electrode layer are not in direct electrical contact.

Example 12 may include the method of example 11, wherein the trench is a plurality of trenches in substantially parallel planes.

Example 13 may include the method of example 11, wherein etching a trench further comprises etching a trench using laser-assisted etching of glass interconnects (LEGIT) techniques.

Example 14 may include the method of example 11, wherein a first side of the trench and a second side of the trench opposite the first side of the trench form a V-shape.

Example 15 may include the method of any one of examples 11-14, further comprising: electrically coupling a first electrical contact on the first side of the glass substrate with the bottom electrode layer; and electrically coupling a second electrical contact on the first side of the glass substrate with the top electrode layer.

Example 16 is a package comprising: a substrate that includes a redistribution layer (RDL) coupled with a first side of a glass core, the glass core having the first side and a second side opposite the first side; a capacitor at the first side of the glass core, the capacitor comprising: a trench in the first side of the glass core, the trench extending from the first side of the glass core toward the second side of the glass core; a continuous layer of material coupled with a portion of the first side of the glass core at a first location, the layer extending from the first location onto a surface of the trench and to a second location of the first side of the glass core, the first location and the second location on opposite sides of the trench; and wherein the capacitor is electrically coupled with the RDL; and a die coupled with the RDL and electrically coupled with the capacitor.

Example 17 may include the package of example 16, wherein the layer of material further includes three discrete layers: a bottom electrode layer, a center capacitor layer, and a top electrode layer.

Example 18 may include the package of example 16, wherein the RDL is a first RDL and the capacitor is a first capacitor; and further comprising: a second RDL coupled with the second side of the glass core; a second capacitor at the second side of the glass core, the second capacitor comprising: a trench in the second side of the glass core, the trench extending from the second side of the glass core toward the first side of the glass core; a continuous layer of material coupled with a portion of the second side of the glass core at a first location, the layer extending from the first location onto a surface of the trench and to a second location of the second side of the glass core, the first location and the second location on opposite sides of the trench; and wherein the second capacitor is electrically coupled with the second RDL.

Example 19 may include the package of example 18, wherein the glass core further includes a plane substantially perpendicular to the first side of the glass core that electrically couples the first RDL and the second RDL.

Example 20 may include the package of any one of example 16-19, wherein a width of the trench is 10 μm or the depth of the trench is at least 250 μm.

What is claimed is:

1. A capacitor comprising:
a glass substrate having a first side and a second side opposite the first side;
a trench in the first side of the substrate, the trench extending from the first side of the substrate toward the second side of the substrate; and
a continuous layer of material coupled with a portion of the first side of the glass substrate at a first location, the layer extending from the first location onto a surface of the trench and to a second location of the first side of the glass substrate, the first location and the second location on opposite sides of the trench.

2. The capacitor of claim 1, wherein the trench is a plurality of trenches in substantially parallel planes.

3. The capacitor of claim 2, wherein a distance between each of the plurality of trenches is less than 2 nm.

4. The capacitor of claim 1, wherein a bottom of the trench is substantially parallel to the first side of the glass substrate.

5. The capacitor of claim 1, wherein a side of the trench is substantially perpendicular to the first side of the glass substrate.

6. The capacitor of claim 1, wherein a first side of the trench and a second side of the trench opposite the first side of the trench form a V shape.

7. The capacitor of claim 1, wherein the layer of material includes a plurality of capacitor layers interleaved with a plurality of electrode layers.

8. The capacitor of claim 7, wherein the trench includes a dielectric coupled with the top electrode layer.

9. The capacitor of claim 7, further comprising:
a first electrical contact at the first location of the first side of the glass substrate electrically coupled with the bottom electrode layer; and
a second electrical contact at the second location of the first side of the glass substrate electrically coupled with the top electrode layer.

10. The capacitor of claim 1, wherein the glass substrate is a glass core.

11. A method comprising:
etching a trench on a first side of a glass substrate, the trench extending from a first side of the glass substrate toward a second side of the glass substrate opposite the first side;
depositing a continuous bottom electrode layer on a surface of the trench and on a surface of the glass substrate on either side of the trench;
depositing a continuous capacitor layer on the bottom electrode layer; and
depositing a continuous top electrode layer on the capacitor layer, wherein the bottom electrode layer and the top electrode layer are not in direct electrical contact.

12. The method of claim 11, wherein the trench is a plurality of trenches in substantially parallel planes.

13. The method of claim 11, wherein etching a trench further comprises etching a trench using laser-assisted etching of glass interconnects (LEGIT) techniques.

14. The method of claim 11, wherein a first side of the trench and a second side of the trench opposite the first side of the trench form a V-shape.

15. The method of claim 11, further comprising:
electrically coupling a first electrical contact on the first side of the glass substrate with the bottom electrode layer; and
electrically coupling a second electrical contact on the first side of the glass substrate with the top electrode layer.

16. A package comprising:
a substrate that includes a redistribution layer (RDL) coupled with a first side of a glass core, the glass core having the first side and a second side opposite the first side;
a capacitor at the first side of the glass core, the capacitor comprising:
a trench in the first side of the glass core, the trench extending from the first side of the glass core toward the second side of the glass core;
a continuous layer of material coupled with a portion of the first side of the glass core at a first location, the layer extending from the first location onto a surface of the trench and to a second location of the first side of the glass core, the first location and the second location on opposite sides of the trench; and
wherein the capacitor is electrically coupled with the RDL; and
a die coupled with the RDL and electrically coupled with the capacitor.

17. The package of claim 16, wherein the layer of material further includes three discrete layers: a bottom electrode layer, a center capacitor layer, and a top electrode layer.

18. The package of claim 16, wherein the RDL is a first RDL and the capacitor is a first capacitor; and further comprising:
a second RDL coupled with the second side of the glass core;
a second capacitor at the second side of the glass core, the second capacitor comprising:
a trench in the second side of the glass core, the trench extending from the second side of the glass core toward the first side of the glass core;
a continuous layer of material coupled with a portion of the second side of the glass core at a first location, the layer extending from the first location onto a surface of the trench and to a second location of the second side of the glass core, the first location and the second location on opposite sides of the trench; and
wherein the second capacitor is electrically coupled with the second RDL.

19. The package of claim 18, wherein the glass core further includes a plane substantially perpendicular to the first side of the glass core that electrically couples the first RDL and the second RDL.

20. The package of claim 16, wherein a width of the trench is 10 μm or the depth of the trench is at least 250 μm.
